(19) United States
(12) Patent Application Publication
(10) Pub. No.: US 2025/0048739 A1
(43) Pub. Date: Feb. 6, 2025

(54) THIN FILM TRANSISTOR SUBSTRATE AND DISPLAY APPARATUS COMPRISING THE SAME

(71) Applicant: LG DISPLAY CO., LTD., Seoul (KR)

(72) Inventors: ChanYong JEONG, Paju-si (KR); JuHeyuck BAECK, Paju-si (KR); Dohyung LEE, Paju-si (KR); Younghyun KO, Paju-si (KR); HongRak CHOI, Paju-si (KR); Dohyun KWAK, Paju-si (KR)

(73) Assignee: LG DISPLAY CO., LTD., Seoul (KR)

(21) Appl. No.: 18/783,662

(22) Filed: Jul. 25, 2024

(30) Foreign Application Priority Data
Aug. 4, 2023 (KR) 10-2023-0101894

(51) Int. Cl. H01L 27/12; H01L 25/16

(52) U.S. Cl. CPC H01L 27/1225; H01L 25/167

(57) ABSTRACT

A thin film transistor substrate includes a thin film transistor, on a substrate, including an active layer; a conductive material layer; and a gate electrode spaced apart and partially overlapping the active layer. The active layer includes a channel area partially overlapping the gate electrode, and a source area and a drain area connected to respective sides of the channel area. The conductive material layer includes a first and second conductive material layer respectively on the source drain areas. The first conductive material layer overlaps at least a portion of the channel area. The active layer includes an active hole in which the active layer is absent within an area defined by the active layer, and, in a plan view, the active hole extends from the channel area to the drain area.

### CROSS-REFERENCE TO RELATED APPLICATIONS

This application claims the benefit of priority of the Korean Patent Application No. 10-2023-0101894 filed on Aug. 4, 2023, which is hereby incorporated by reference as if fully set forth herein.

### BACKGROUND

### Technical Field

The present disclosure relates to a thin film transistor substrate and a display apparatus including the same.

### Discussion of the Related Art

Transistors are widely used as switching devices or driving devices in the field of electronic devices. In particular, because a thin film transistor may be manufactured on a glass substrate or a plastic substrate, it is widely used as a switching device of a display apparatus, such as a liquid crystal display apparatus or an organic light emitting device.

Based on the material constituting the active layer, thin film transistors can be divided into amorphous silicon thin film transistors using amorphous silicon as the active layer, polycrystalline silicon thin film transistors using polycrystalline silicon as the active layer, and oxide semiconductor thin film transistors using oxide semiconductors as the active layer. The amorphous silicon thin film transistor (a-Si TFT) has the advantage of short manufacturing process time and low production cost because amorphous silicon can be deposited in a short time to form an active layer, but has the disadvantage of being limited in use in active matrix organic light emitting devices (AMOLEDs) because of low mobility and poor current driving ability and a change in threshold voltage.

Polycrystalline silicon thin film transistor (poly-Si TFT) is made by crystallizing amorphous silicon after amorphous silicon is deposited. Because a process of crystallizing amorphous silicon is required in the manufacturing process of a polycrystalline silicon thin film transistor, the manufacturing cost increases as the number of processes increases, and because the crystallization process is performed at a high process temperature, it is difficult to apply the polycrystalline silicon thin film transistor to a large area device. In addition, due to its polycrystalline properties, it is difficult to secure the uniformity of the polycrystalline silicon thin film transistor.

In an oxide semiconductor thin film transistor (TFT), because the oxide constituting the active layer can be formed at a relatively low temperature, has high mobility, and has a large resistance change according to the oxygen content, desired physical properties can be easily obtained. Also, due to the nature of the oxide, because the oxide semiconductor is transparent, it is also advantageous to implement a transparent display.

In the case of an oxide semiconductor thin film transistor, it may be vulnerable to exposure to light or hydrogen, and in this case, a structural change for controlling light or hydrogen exposure is required. Accordingly, technologies for controlling light or hydrogen exposure are being studied.

### SUMMARY

Accordingly, embodiments of the present disclosure are directed to a thin film transistor substrate and a display apparatus including the same that substantially obviates one or more of the problems due to limitations and disadvantages of the related art.

An aspect of the present disclosure is to provide a thin film transistor substrate that includes an active hole to prevent or suppress exposure to hydrogen and light.

Another aspect of the present disclosure is to provide a thin film transistor substrate that includes an active hole to prevent or suppress a threshold voltage Vth from being shifted in a negative (−) direction even if the channel area has a large width.

Another aspect of the present disclosure is to provide a thin film transistor substrate that includes a conductive material layer overlapping a channel area to prevent or suppress exposure of hydrogen and light.

Another aspect of the present disclosure is to provide a thin film transistor substrate having improved reliability by including a pattern of an active layer and including a conductive material layer overlapping a channel area.

Another aspect of the present disclosure is to provide a thin film transistor substrate capable of ensuring capacitor area optimization by including an active hole and a conductive material layer overlapping a channel area.

Another aspect of the present disclosure is to provide a display apparatus including such a thin film transistor substrate.

Additional features and aspects will be set forth in the description that follows, and in part will be apparent from the description, or may be learned by practice of the inventive concepts provided herein. Other features and aspects of the inventive concepts may be realized and attained by the structure particularly pointed out in the written description, or derivable therefrom, and the claims hereof as well as the appended drawings.

To achieve these and other aspects of the inventive concepts, as embodied and broadly described herein, a thin film transistor substrate comprises a substrate; a thin film transistor on the substrate, wherein the thin film transistor includes: an active layer; a conductive material layer on the active layer; and a gate electrode spaced apart from the active layer and partially overlapping the active layer, wherein the active layer includes: a channel area partially overlapping the gate electrode in a plan view; a source area connected to one side of the channel area in the plan view; and a drain area connected to the other side of the channel area in the plan view, wherein the conductive material layer includes: a first conductive material layer on the source area; and a second conductive material layer on the drain area, wherein the first conductive material layer overlaps at least a portion of the channel area, wherein the active layer includes an active hole in which the active layer is absent within an area defined by the active layer, and wherein, in the plan view, the active hole extends from the channel area to the drain area.

It is to be understood that both the foregoing general description and the following detailed description are exemplary and explanatory and are intended to provide further explanation of the inventive concepts as claimed.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain various principles. In the drawings:

FIG. 1 is a plan view of a thin film transistor substrate according to an embodiment of the present disclosure.

FIG. 2 is a cross-sectional view taken along line I-I′ of FIG. 1.

FIG. 3 is a cross-sectional view taken along line II-II′ of FIG. 1.

FIG. 4 is a plan view of a thin film transistor substrate according to another embodiment of the present disclosure.

FIG. 5 is a cross-sectional view taken along line I-I′ of FIG. 4.

FIG. 6 is a cross-sectional view taken along line II-II′ of FIG. 4.

FIG. 7 is a cross-sectional view of a thin film transistor substrate according to another embodiment of the present disclosure.

FIG. 8 is a cross-sectional view of a thin film transistor substrate according to another embodiment of the present disclosure.

FIG. 9 is a schematic diagram illustrating a capacitor of the present disclosure.

FIG. 10 is a cross-sectional view of a thin film transistor substrate according to an embodiment for describing the capacitor of the present disclosure.

FIG. 11 is a cross-sectional view of a thin film transistor substrate according to a comparative example for describing the capacitor of the present disclosure.

FIG. 12A is a plan view of a thin film transistor substrate according to another embodiment of the present disclosure.

FIG. 12B is a cross-sectional view taken along line I-I′ of FIG. 12A.

FIG. 13 is a schematic diagram of a display apparatus according to an embodiment of the present disclosure.

FIG. 14 is a schematic diagram of a shift register.

FIG. 15 is a circuit diagram of any one pixel of FIG. 13.

FIG. 16 is a plan view of the pixel of FIG. 15.

FIG. 17 is a cross-sectional view taken along line III-III′ of FIG. 16.

FIG. 18 is a circuit diagram of any one pixel of a display apparatus according to another embodiment of the present disclosure.

FIG. 19 is a circuit diagram of any one pixel of a display apparatus according to another embodiment of the present disclosure.

### DETAILED DESCRIPTION

Advantages and features of the present disclosure and implementation methods thereof will be clarified through following embodiments described with reference to the accompanying drawings. The present disclosure may, however, be embodied in different forms and should not be construed as limited to the embodiments set forth herein. Rather, these embodiments are provided so that this disclosure will be thorough and complete and will fully convey the scope of the present disclosure to those skilled in the art.

A shape, a size, a ratio, an angle and a number disclosed in the drawings for describing embodiments of the present disclosure are merely an example and thus, the present disclosure is not limited to the illustrated details. Like reference numerals refer to like elements throughout the specification. In the following description, when the detailed description of the relevant known function or configuration is determined to unnecessarily obscure the important point of the present disclosure, the detailed description will be omitted.

In a case where “comprise,” “have” and “include” described in the present disclosure are used, another portion may be added unless “only˜” is used. The terms of a singular form may include plural forms unless referred to the contrary.

In construing an element, the element is construed as including an error band although there is no explicit description.

In describing a position relationship, for example, when the position relationship is described as “upon˜,” “above˜,” “below˜,” and “next to˜,” one or more portions may be disposed between two other portions unless “just” or “direct” is used.

Spatially relative terms, such as “below,” “beneath,” “lower,” “above,” and “upper,” may be used herein to easily describe a relationship of one element or elements to another element or elements as illustrated in the drawings. It will be understood that these terms are intended to encompass different orientations of the device in addition to the orientation depicted in the drawings. For example, if the device illustrated in the figure is reversed, the device described to be arranged “below,” or “beneath” another device may be arranged “above” another device. Therefore, an exemplary term “below or beneath” may include “below or beneath” and “above” orientations. Likewise, an exemplary term “above” or “on” may include “above” and “below or beneath” orientations.

In describing a temporal relationship, for example, when the temporal order is described as “after,” “subsequent,” “next,” and “before,” a case which is not continuous may be included, unless “just” or “direct” is used.

It will be understood that, although the terms “first,” “second,” etc. may be used herein to describe various elements, these elements should not be limited by these terms. These terms are only used to distinguish one element from another. For example, a first element could be termed a second element, and, similarly, a second element could be termed a first element, without departing from the scope of the present disclosure.

It should be understood that the term “at least one” includes all combinations related with any one item. For example, “at least one among a first element, a second element and a third element” may include all combinations of two or more elements selected from the first, second and third elements as well as each element of the first, second and third elements.

Features of various embodiments of the present disclosure may be partially or overall coupled to or combined with each other and may be variously inter-operated with each other and driven technically as those skilled in the art can sufficiently understand. The embodiments of the present disclosure may be carried out independently from each other or may be carried out together in a co-dependent relationship.

In the addition of reference numerals to the components of each drawing describing embodiments of the present disclosure, the same components can have the same sign as can be displayed on the other drawings.

In the embodiments of the present disclosure, a source electrode and a drain electrode are distinguished for convenience of description, and the source electrode and the drain electrode may be interchanged. The source electrode may be the drain electrode and vice versa. In addition, the source electrode of any one embodiment may be a drain electrode in another embodiment, and the drain electrode of any one embodiment may be a source electrode in another embodiment.

In some embodiments of the present disclosure, for convenience of description, a source area is distinguished from a source electrode, and a drain area is distinguished from a drain electrode, but embodiments of the present disclosure are not limited thereto. The source area may be the source electrode, and the drain area may be the drain electrode. In addition, the source area may be the drain electrode, and the drain area may be the source electrode.

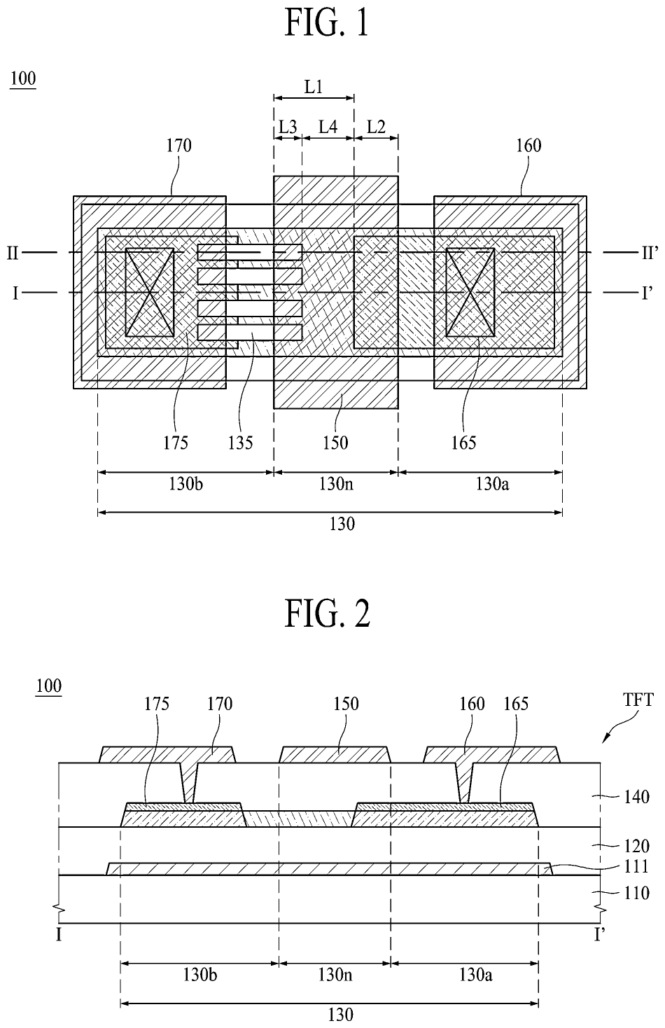

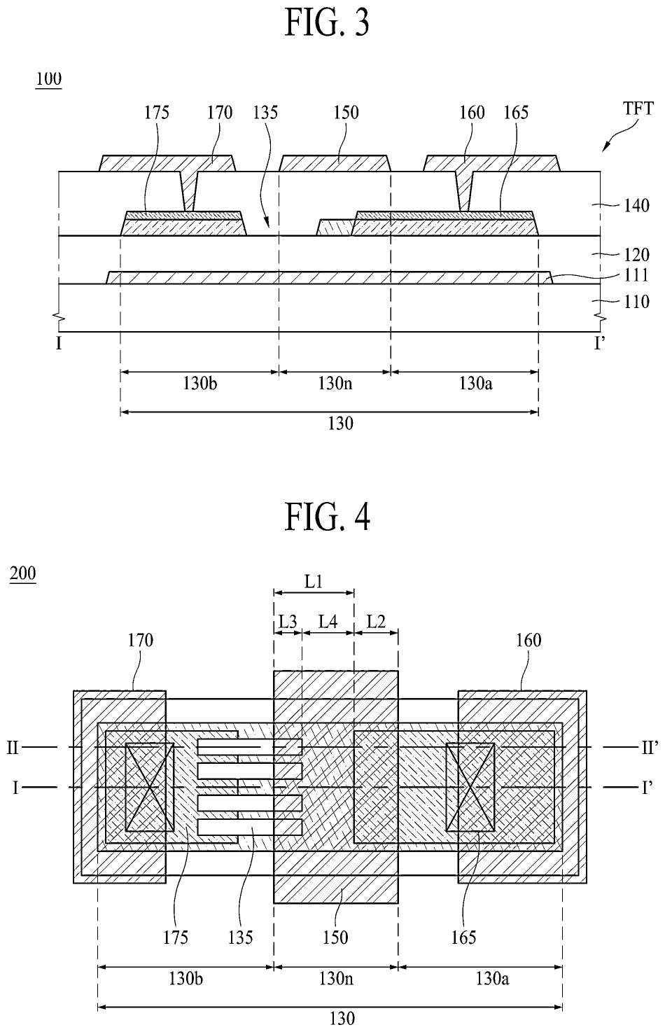

FIG. 1 is a plan view of a thin film transistor substrate 100 according to an embodiment of the present disclosure. FIG. 2 is a cross-sectional view taken along line I-I′ of FIG. 1. FIG. 3 is a cross-sectional view taken along line II-II′ of FIG. 1.

With reference to FIGS. 1, 2, and 3, the thin film transistor substrate 100 according to an embodiment of the present disclosure may include a thin film transistor TFT on a base substrate 110, and the thin film transistor TFT may include an active layer 130, a gate electrode 150, and conductive material layers 165 and 175. A gate electrode 150 spaced apart from the active layer 130 and partially overlapping the active layer 130 and conductive material layers 165 and 175 on the active layer 130 may be included.

According to an embodiment of the present disclosure, the thin film transistor substrate 100 may further include a base substrate 110. As illustrated in FIGS. 2 and 3, the active layer 130 is disposed on the base substrate 110.

The thin film transistor substrate 100 according to an embodiment of the present disclosure may further include a buffer layer 120. In FIGS. 2 and 3, the active layer 130 is disposed on the buffer layer 120. The buffer layer 120 may be disposed between the base substrate 110 and the active layer 130.

The thin film transistor substrate 100 according to an embodiment of the present disclosure may further include a gate insulating layer 140. In FIGS. 2 and 3, the gate insulating layer 140 is disposed on the active layer 130. The gate insulating layer 140 may be disposed between the active layer 130 and the gate electrode 150.

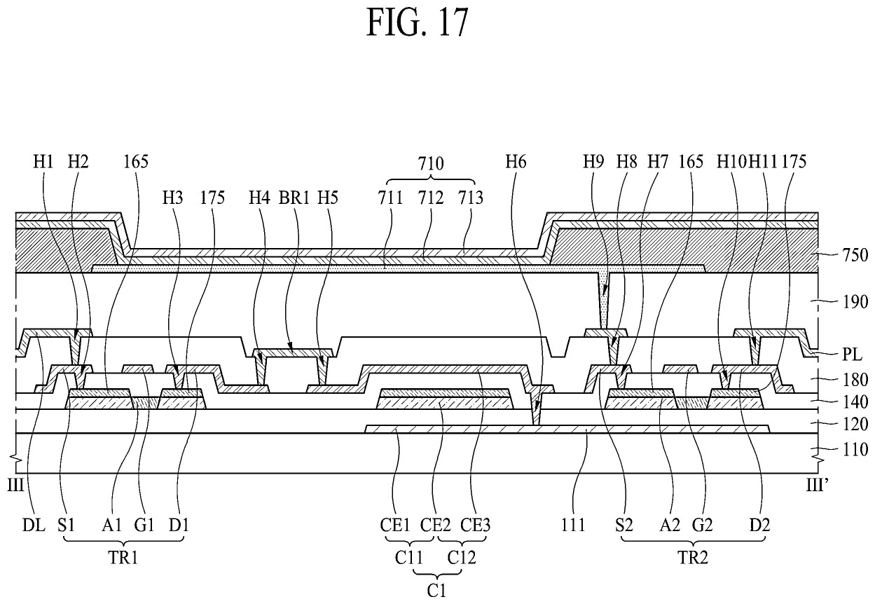

According to an embodiment of the present disclosure, the thin film transistor substrate 100 may further include another layer disposed on the gate electrode 150. In detail, the thin film transistor substrate 100 may further include an interlayer insulating layer 180. With reference to FIG. 17, the interlayer insulating layer 180 is disposed on the gate electrode 150. In detail, the gate electrode 150 is disposed between the gate insulating layer 140 and the interlayer insulating layer 180.

According to an embodiment of the present disclosure, the thin film transistor substrate 100 may further include a source electrode 160 and a drain electrode 170. In FIGS. 1, 2, and 3, the source electrode 160 and the drain electrode 170 are disposed on the gate insulation layer 140.

Hereinafter, components of the thin film transistor substrate 100 according to an embodiment of the present disclosure will be described in more detail.

Glass or plastic may be used as the base substrate 110. A transparent plastic having flexible characteristics as plastic, for example, polyimide, may be used. When polyimide is used as the base substrate 110, considering that a high-temperature deposition process is performed on the base substrate 110, heat-resistant polyimide capable of withstanding high-temperature may be used. In this case, in order to form a thin film transistor, processes, such as deposition, etching, and the like, may be performed in a state in which a polyimide substrate is disposed on a carrier substrate made of a highly durable material, such as glass.

As shown in FIGS. 2 and 3, a buffer layer 120 may be disposed on the base substrate 110. The buffer layer 120 may be formed on the base substrate 110 and may be formed of an inorganic material or an organic material. For example, insulating oxides, such as silicon oxide (SiOx), aluminum oxide (Al2O3) and the like, may be included. The buffer layer 120 blocks impurities, such as moisture and oxygen, flowing from the base substrate 110 to protect the active layer 130, planarize the upper portion of the base substrate 110, and may be formed as a single layer or a plurality of layers.

As shown in FIGS. 2 and 3, the active layer 130 may be disposed on the buffer layer 120. The active layer 130 may include a channel area 130n, a source area 130a, and a drain area 130b.

The active layer 130 may include a channel area 130n partially overlapping the gate electrode 150 in a plane, a source area 130a connected to one side of the channel area 130n without overlapping the gate electrode 150 in a plane, and a drain area 130b connected to the other side of the channel area 130n without overlapping the gate electrode 150 in a plane.

According to an embodiment of the present disclosure, the source area 130a and the drain area 130b are spaced apart from each other with the channel area 130n interposed therebetween.

According to a configuration of the present disclosure, the active layer 130 may be formed of a semiconductor material. The active layer 130 may include an oxide semiconductor material. The oxide semiconductor material may include at least one of an IZO (InZnO)-based oxide semiconductor material, an IGO (InGaO)-based oxide semiconductor material, an ITO (InSnO)-based oxide semiconductor material, an IGZO (InGaZnO)-based oxide semiconductor material, an IGZTO (InGaZnSnO)-based oxide semiconductor material, a GZTO (GaZnSnO)-based oxied semiconductor material, a GZO (GaZnO)-based oxide semiconductor material, an ITZO (InSnZnO)-based oxide semiconductor material, and a FIZO (FeInZnO)-based oxide semiconductor material. However, an embodiment of the present disclosure is not limited thereto, and the active layer 130 may be made of another oxide semiconductor material known in the art.

The source area 130a and the drain area 130b may be formed by selective conductorization with respect to the active layer 130 made of a semiconductor material. According to an embodiment of the present disclosure, conductorization is imparted to a specific portion of the active layer 130 so that the same function as a conductor is called selective conductorization.

For example, the active layer 130 may be selectively conductive by ion doping. As a result, the source area 130a and the drain area 130b may be formed. However, embodiments of the present disclosure are not limited thereto, and the active layer 130 may be selectively conductive by other methods known in the art.

The source area 130a and the drain area 130b do not overlap the gate electrode 150. The source area 130a and the drain area 130b have better electrical conductivity and higher mobility than the channel area 130n. Accordingly, the source area 130a and the drain area 130b may function as a wiring, respectively.

In FIGS. 1 and 3, an active hole 135 in which the active layer 130 is not disposed is disposed in an area in which an edge is defined by the active layer 130. According to an embodiment of the present disclosure, the active hole 135 is disposed in an area defined by the active layer 130 on a plane. The active hole 135 may be an area formed by removing a portion of the active layer 130.

With reference to FIGS. 1 and 3, because the active hole 135 may be referred to as a hole formed in the active layer 130 by removing a part of the active layer 130, according to an embodiment of the present disclosure, the hole is referred to as an “active hole.”

According to an embodiment of the present disclosure, the active hole 135 may protrude in a direction from the gate electrode 150 toward the drain area 130b in a plan view. Further, the active layer 130 may not be disposed in some regions of the drain area 130b.

In FIGS. 1 and 3, a configuration in which the active hole 135 protrudes in the direction of the drain area 130b from the gate electrode 150 is illustrated in a plan view.

According to an embodiment of the present disclosure, a portion of the active hole 135 may overlap the gate electrode 150. FIGS. 1 and 3 illustrate a configuration in which a portion of the active hole 135 overlaps the gate electrode 150.

Further, the active layer 130 may not be disposed in some regions of the channel area 130n. According to an embodiment of the present disclosure, the active hole 135 may be formed by patterning the active layer 130. The active hole 135 may be an area in which a periphery thereof is surrounded by the active layer 130. For example, the active hole 135 may be a portion from which the active layer 130 is partially patterned and removed.

In general, when the channel area 130n of the active layer 130 has a large channel width, conductive diffusion may be greatly performed in a boundary region between the channel area 130n and the drain area 130b. When conductive diffusion proceeds, a threshold voltage (Vth) of the thin film transistor may move in a negative (−) direction, and thus driving stability of the thin film transistor may be deteriorated.

When the channel area 130n of the active layer 130 has a small channel width, conductive diffusion may decrease at a boundary region between the channel area 130n, the source area 130a, and the drain area 130b. On the contrary, when the channel area 130n of the active layer 130 has a small channel width, the total amount of carriers passing through the channel area 130n of the thin film transistor may decrease, and ON current characteristics may be deteriorated. As a result, when a large amount of current flows through the thin film transistor having a small channel width in the channel area 130n, the thin film transistor may be damaged and thus driving stability may be deteriorated. Accordingly, there is a need to control conductive diffusion while the active layer 130 has a large channel width.

According to an embodiment of the present disclosure, when the active hole 135 is formed to overlap the gate electrode 150, a boundary portion of the channel area 130n and the drain area 130b of the active layer 130 is patterned such that conduction is performed in a region other than the active hole in the channel area 130n of the active layer 130. As a result, even when the channel area 130n of the active layer 130 has a large channel width, the width of the region in which conduction is performed is narrowed, such that penetration of conduction into the channel area 130n may be prevented or controlled, and penetration of light or hydrogen into the channel area 130n of the active layer 130 may be suppressed or prevented.

According to an embodiment of the present disclosure, the active hole 135 may have a plurality of sub-active holes. FIG. 1 illustrates a configuration in which the active hole 135 has a plurality of sub-active holes. When the active hole 135 has a plurality of sub-active holes, each sub-active hole overlaps at least a portion of the gate electrode 150. Also, when the active hole 135 has a plurality of sub-active holes, each sub-active hole is spaced apart from each other. However, an embodiment of the present disclosure is not limited thereto, and the active hole 135 may have a single sub-active hole.

According to an embodiment of the present disclosure, the active hole 135 may have a rectangular shape. However, an embodiment of the present disclosure is not limited thereto, and the active hole 135 according to an embodiment of the present disclosure may have various shapes.

According to an embodiment of the present disclosure, the thin film transistor substrate 100 may include conductive material layers 165 and 175 on the active layer 130.

As shown in FIGS. 1, 2, and 3, the conductive material layers 165 and 175 may include a first conductive material layer 165 on the source area 130a and a second conductive material layer 175 on the drain area 130b. The first conductive material layer 165 and the second conductive material layer 175 are disposed to be spaced apart from each other with a part of the channel area 130n interposed therebetween. The source area 130a and the drain area 130b may be disposed between the base substrate 110, the first conductive material layer 165, and the second conductive material layer 175, respectively. The first conductive material layer 165 and the second conductive material layer 175 may contact the active layer 130 through the source area 130a and the drain area 130b, respectively.

According to an embodiment of the present disclosure, the first conductive material layer 165 may overlap at least a portion of the channel area 130n. In FIGS. 1, 2, and 3, a configuration in which the first conductive material layer 165 overlaps the channel area 130n is illustrated. For example, the first conductive material layer 165 may overlap at least a portion of the gate electrode 150.

According to an embodiment of the present disclosure, when the first conductive material layer 165 overlaps the channel area 130n, the first conductive material layer 165 may protect the boundary region between the source area 130a and the channel area 130n from external light or hydrogen. Therefore, the channel area 130n of the active layer 130 may be protected from external light or hydrogen.

According to an embodiment of the present disclosure, the second conductive material layer 175 may not be disposed on the active hole 135. For example, a configuration in which the second conductive material layer 175 is not disposed on the active hole 135 is shown in FIGS. 1 and 3.

According to an embodiment of the present disclosure, the active hole 135 may be disposed to be spaced apart from the first conductive material layer 165. The active hole 135 may not overlap at least a portion of the gate electrode 150. FIG. 1 illustrates a configuration in which the active hole 135 is disposed to be spaced apart from the first conductive material layer 165 in a plan view.

According to an embodiment of the present disclosure, the first conductive material layer 165 overlaps the channel area 130n, while the second conductive material layer 175 may be disposed to be spaced apart from the channel area 130n.

In the case of the source area 130a of the active layer 130, the first conductive material layer 165 may overlap the channel area 130n to protect the channel area 130n from external light or hydrogen, and in the case of the drain area 130b of the active layer 130, the active hole 135 may overlap the gate electrode 150 to protect the channel area 130n from external light or hydrogen.

According to one embodiment of the present disclosure, the conductive material layers 165 and 175 may include at least one selected from titanium (Ti), molybdenum (Mo), aluminum (Al), silver (Ag), copper (Cu), chromium (Cr), tantalum (Ta), neodium (Nd), calcium (Ca), barium (Ba), and transparent conductive oxide (TCO). The conductive material layers 165 and 175 may have reducibility. According to one embodiment of the present disclosure, the transparent conductive oxide (TCO) may include ITO (InSnO), IZO (InZnO), IO (InO), TO (SnO), and ZO (ZnO).

The active layer 130 may be selectively conductive by the conductive material layers 165 and 175. According to an embodiment of the present disclosure, the source area 130a and the drain area 130b are in contact with the first conductive material layer 165 and the second conductive material layer 175, respectively. A region of the active layer 130 in contact with the first conductive material layer 165 and the second conductive material layer 175 is conductive to form a source area 130a and a drain area 130b, respectively.

According to an embodiment of the present disclosure, parts of the active layer 130 contacting the conductive material layers 165 and 175 may be reduced, respectively, to form the source area 130a and the drain area 130b.

For example, when a part of the active layer 130 contacting and overlapping the conductive material layers 165 and 175 is reduced, oxygen vacancies occur in the active layer 130, and accordingly, the active layer 130 may be selectively conductorized. By selective reduction of the active layer 130, the source area 130a and the drain area 130b may be formed. According to an embodiment of the present disclosure, the active layer 130 may be selectively conductorized by the conductive material layers 165 and 175 without a separate conductive process, such as plasma treatment, ion doping, or ultraviolet treatment.

As shown in FIG. 1, when the shortest distance from the drain area 130b to the first conductive material layer 165 is defined as a first length L1 and the shortest length of a region in which the first conductive material layer 165 overlaps the gate electrode 150 in the channel length direction of the active layer 130 is defined as a second length L2, the first length L1 may be longer than the second length L2. Accordingly, light and hydrogen incident from the outside from the source area 130a of the active layer 130 may be efficiently blocked, and as a result, reliability of the thin film transistor may be improved.

On the other hand, when the second length L2 is longer than the first length L1, the first conductive material layer 165 may excessively overlap the gate electrode 150, such that the channel area 130n of the active layer 130 may become excessively conductive. Accordingly, the threshold voltage Vth of the thin film transistor may move in the negative (−) direction, and thus the driving stability of the thin film transistor may be deteriorated.

As shown in FIG. 1, if the shortest length of a region in which the active hole 135 overlaps the gate electrode 150 in the channel length direction of the active layer 130 is defined as a third length L3, and the shortest distance from the active hole 135 to the first conductive material layer 165 in the channel length direction of the active layer 130 is defined as a fourth length L4, the fourth length LA may be longer than the third length L3. Accordingly, light and hydrogen incident from the outside from the drain area 130b of the active layer 130 may be efficiently blocked, and as a result, reliability of the thin film transistor may be improved.

On the contrary, when the third length L3 is longer than the fourth length L4, the active hole 135 may excessively penetrate into the channel area 130n, and thus the total amount of carriers passing through the channel area 130n of the thin film transistor may decrease and ON current characteristics may be deteriorated. As a result, when a large amount of current flows through the thin film transistor, the thin film transistor may be damaged and thus driving stability may be deteriorated.

According to an embodiment of the present disclosure, the thin film transistor substrate 100 may further include a source electrode 160 and a drain electrode 170.

The source electrode 160 and the drain electrode 170 may be disposed on the gate insulating layer 140 and may be disposed on the same layer as the gate electrode 150. The source electrode 160 and the drain electrode 170 may be made of the same material as the gate electrode 150 by the same process.

Each of the source electrode 160, the drain electrode 170, and the gate electrode 150 may include at least one of an aluminum-based metal, such as aluminum (Al) or an aluminum alloy, a silver-based metal, such as silver (Ag) or a silver alloy, a copper-based metal, such as copper (Cu) or a copper alloy, a molybdenum-based metal, such as molybdenum (Mo) or a molybdenum alloy, chromium (Cr), tantalum (Ta), neodium (Nd), and titanium (Ti). The source electrode 160, the drain electrode 170, and the gate electrode 150 may have a multilayer structure including at least two conductive films having different physical properties.

In FIGS. 2 and 3, the source electrode 160 and the drain electrode 170 are connected to the active layer 130 through contact holes, respectively. The source electrode 160 and the drain electrode 170 are connected to the active layer 130 by contacting the first conductive material layer 165 and the second conductive material layer 175, respectively.

As shown in FIGS. 1, 2, and 3, the light blocking layer 111 may be disposed on the base substrate 110. The light blocking layer 111 may be disposed between the base substrate 110 and the active layer 130. The light blocking layer 111 overlaps the channel area 130n. The light blocking layer 111 blocks light incident from the outside, thereby protecting the channel area 130n.

The light blocking layer 111 may be formed of a material having light blocking characteristics. The light blocking layer 111 may include at least one of an aluminum-based metal, such as aluminum (Al) or an aluminum alloy, a molybdenum-based metal, such as molybdenum (Mo) or a molybdenum alloy, chromium (Cr), tantalum (Ta), neodium (Nd), titanium (Ti), and iron (Fe). According to an embodiment of the present disclosure, the light blocking layer 111 may have electrical conductivity.

The light blocking layer 111 may be omitted. Although not shown in FIGS. 1, 2 and 3, a buffer layer may be additionally disposed between the base substrate 110 and the light blocking layer 111. Although not shown, the light blocking layer 111 may be electrically connected to any one of the source electrode 160 and the drain electrode 170. Also, the light blocking layer 111 may be electrically connected to the gate electrode 150.

According to an embodiment of the present disclosure, the light blocking layer 111 may be disposed to overlap a front surface of the active layer 130. However, an embodiment of the present disclosure is not limited thereto, and the light blocking layer 111 may be disposed not to overlap some regions except for the channel area 130n of the active layer 130.

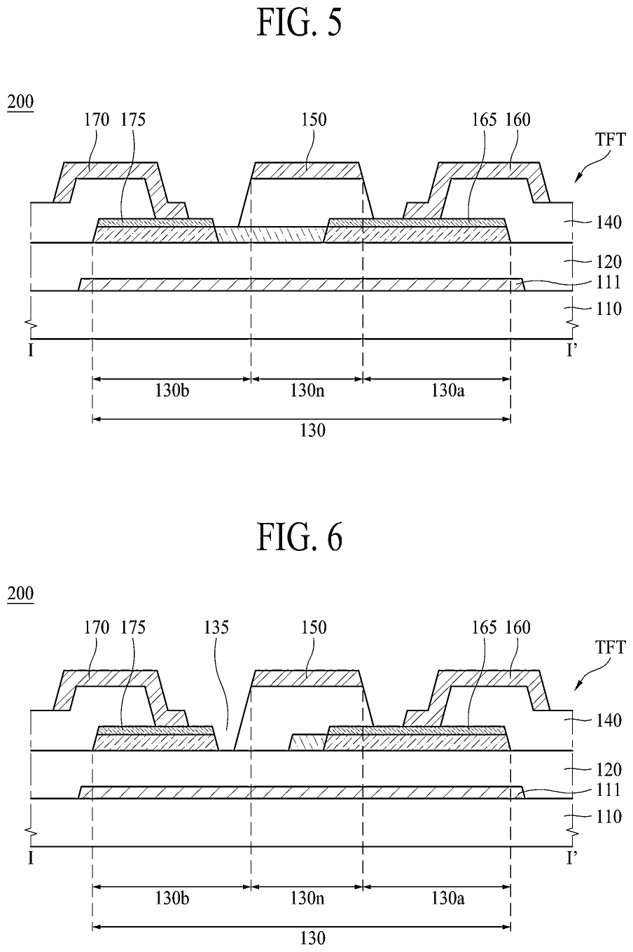

FIG. 4 is a plan view of a thin film transistor substrate 200 according to another embodiment of the present disclosure. FIG. 5 is a cross-sectional view taken along line I-I′ of FIG. 4. FIG. 6 is a cross-sectional view taken along line II-II′ of FIG. 4.

According to an embodiment of the present disclosure, the thin film transistor substrate 200 may further include a gate insulating layer 140 between the active layer 130 and the gate electrode 150. The source area 130a and the drain area 130b of the active layer 130 may be exposed from the gate insulating layer 140. FIGS. 5 and 6 illustrate a configuration in which the source area 130a and the drain area 130b of the active layer 130 are exposed from the gate insulating layer 140.

However, an embodiment of the present disclosure is not limited thereto, and the gate insulating layer 140 may cover the entire upper surface of the active layer 130. FIGS. 2 and 3 show a configuration in which the gate insulating layer 140 covers the entire upper surface of the active layer 130.

The gate insulating layer 140 may include at least one of silicon oxide, silicon nitride, and metal-based oxide. The gate insulating layer 140 may have a single layer structure or a multilayer structure. The gate insulating layer 140 protects the channel area 130n.

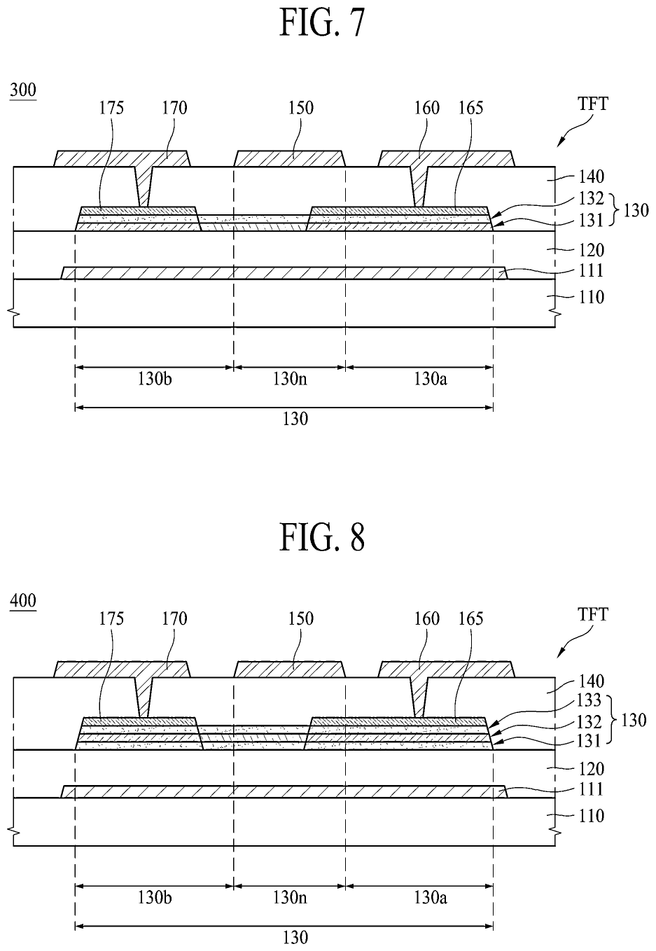

FIG. 7 is a cross-sectional view of a thin film transistor substrate 300 according to another embodiment of the present disclosure, and FIG. 8 is a cross-sectional view of a thin film transistor substrate 400 according to another embodiment of the present disclosure.

According to an embodiment of the present disclosure, the active layer 130 of the thin film transistor substrates 300 and 400 may have a multilayer structure. For example, the active layer 130 may include a first active layer 131 and a second active layer 132.

With reference to FIG. 7, the active layer 130 may include a first active layer 131 and a second active layer 132 on the first active layer 131. The first active layer 131 and the second active layer 132 may include the same semiconductor material, or may include different semiconductor materials.

The first active layer 131 supports the second active layer 132. Accordingly, the first active layer 131 is also referred to as a “support layer.” The active layer 130 has a structure consisting of the first active layer 131 and the second active layer 132 and is also referred to as a bi-layer structure.

According to an embodiment of the present disclosure, the active layer 130 may further include a third active layer 133 on the second active layer 132. Compared with the thin film transistor substrate 300 of FIG. 7, the thin film transistor substrate 400 of FIG. 8 further includes the third active layer 133 on the second active layer 132. However, embodiments of the present disclosure are not limited thereto, and the active layer 130 may further include another semiconductor layer.

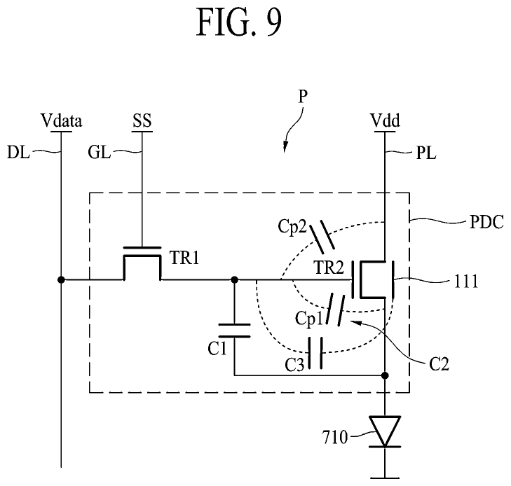

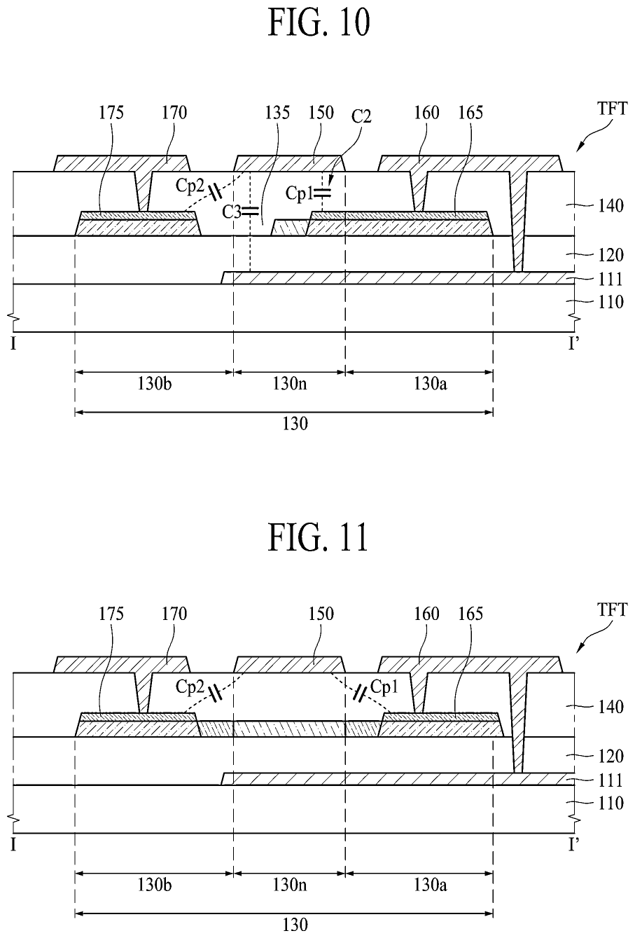

FIG. 9 is a schematic diagram for explaining the capacitor of the present disclosure. FIG. 10 is a cross-sectional view of a thin film transistor substrate according to an embodiment for explaining the capacitor of the present disclosure. FIG. 11 is a cross-sectional view of a thin film transistor substrate according to a comparative example for explaining the capacitor of the present disclosure.

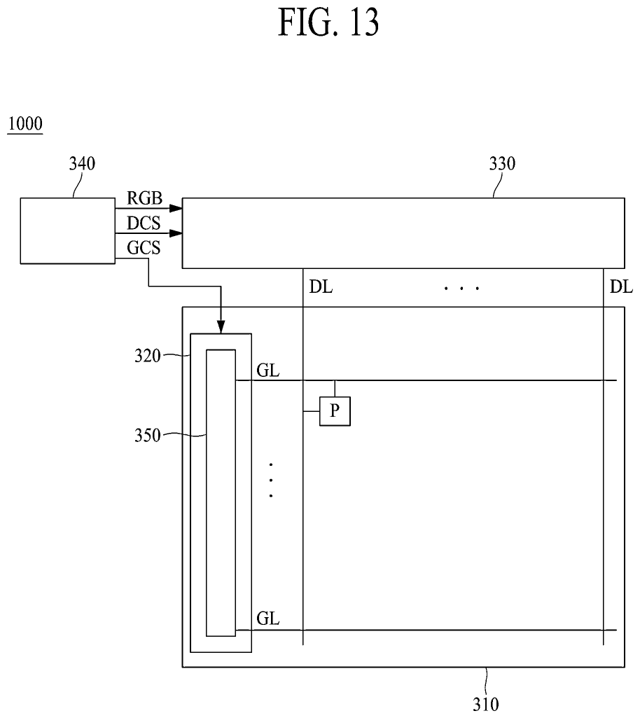

FIG. 9 is a circuit diagram of any pixel P of FIG. 13, and more particularly, an equivalent circuit diagram of the pixel P of the display apparatus 1000 including the organic light emitting diode OLED as the display element 710.

In FIG. 9, the pixel P includes a display element 710 and a pixel driving circuit PDC for driving the display element 710. The pixel driving circuit PDC of FIG. 9 includes a first thin film transistor TR1 which is a switching transistor and a second thin film transistor TR2 which is a driving transistor. The first thin film transistor TR1 is connected to the gate line GL and the data line DL, and is turned on or off by the scan signal SS supplied through the gate line GL. The data line DL provides the data voltage Vdata to the pixel driving circuit PDC, and the first thin film transistor TR1 controls the application of the data voltage Vdata.

The driving power line PL provides a driving voltage Vdd to the display element 710, and the first thin film transistor TR1 controls the driving voltage Vdd. The driving voltage Vdd is a pixel driving voltage for driving the organic light emitting diode OLED that is the display element 710.

When the first thin film transistor TR1 is turned on by the scan signal SS applied through the gate line GL from the gate driver 320, the data voltage Vdata supplied through the data line DL is supplied to the gate electrode of the second thin film transistor TR2 connected to the display element 710. The data voltage Vdata is charged in the first storage capacitor C1 formed between the gate electrode and the source electrode of the second thin film transistor TR2.

FIG. 9 schematically illustrates a capacitor that may be generated when a gate voltage VGS is applied to a thin film transistor according to an embodiment of the present disclosure.

As illustrated in FIGS. 9 and 10, when the gate voltage VGS is applied to the thin film transistor, a first parasitic capacitor Cp1 is formed between the source area 130a of the active layer 130 and the gate electrode 150, and a second parasitic capacitor Cp2 is formed between the drain area 130b of the active layer 130 and the gate electrode 150.

FIG. 10 illustrates a configuration in which the first conductive material layer 165 on the source area 130a is spaced apart from and overlaps the gate electrode 150 to form the first parasitic capacitor Cp1, and the second conductive material layer 175 is spaced apart from the gate electrode 150 to form the second parasitic capacitor Cp2.

On the other hand, FIG. 11 illustrates a configuration in which the first conductive material layer 165 on the source area 130a forms the first parasitic capacitor Cp1 without overlapping the gate electrode 150, and the second conductive material layer 175 is spaced apart from the gate electrode 150 to form the second parasitic capacitor Cp2.

Compared with the thin film transistor substrate of FIG. 11, because the first conductive material layer 165 on the source area 130a overlaps the gate electrode 150 to form the first parasitic capacitor Cp1 in the thin film transistor substrate of FIG. 10, the first parasitic capacitor Cp1 formed on the thin film transistor substrate of FIG. 10 may be greater than the first parasitic capacitor Cp1 formed on the thin film transistor substrate of FIG. 11.

In addition, compared to the thin film transistor substrate in FIG. 11, the second parasitic capacitor Cp2 formed on the thin film transistor substrate in FIG. 10 may be minimized or reduced and may be smaller than the second parasitic capacitor Cp2 formed on the thin film transistor substrate in FIG. 11 because the thin film transistor substrate includes the active hole 135 that protrudes from the gate electrode 150 to the drain area 130b in a plane and overlaps the gate electrode 150.

According to an embodiment of the present disclosure, in the thin film transistor substrate of FIG. 10, the first parasitic capacitor Cp1 is formed by overlapping the gate electrode 150 with the first conductive material layer 165 on the source region 130a, and the thin film transistor substrate includes the active hole 135 protruding from the gate electrode 150 in the direction of the drain region 130b in a plan view, and overlapping the gate electrode 150, such that the first parasitic capacitor Cp1 is maximized or increased and the second parasitic capacitor Cp2 is minimized or reduced. That is, the first parasitic capacitor Cp1 may be greater than the second parasitic capacitor Cp2. Therefore, the first parasitic capacitor Cp1 may function as the second storage capacitor C2.

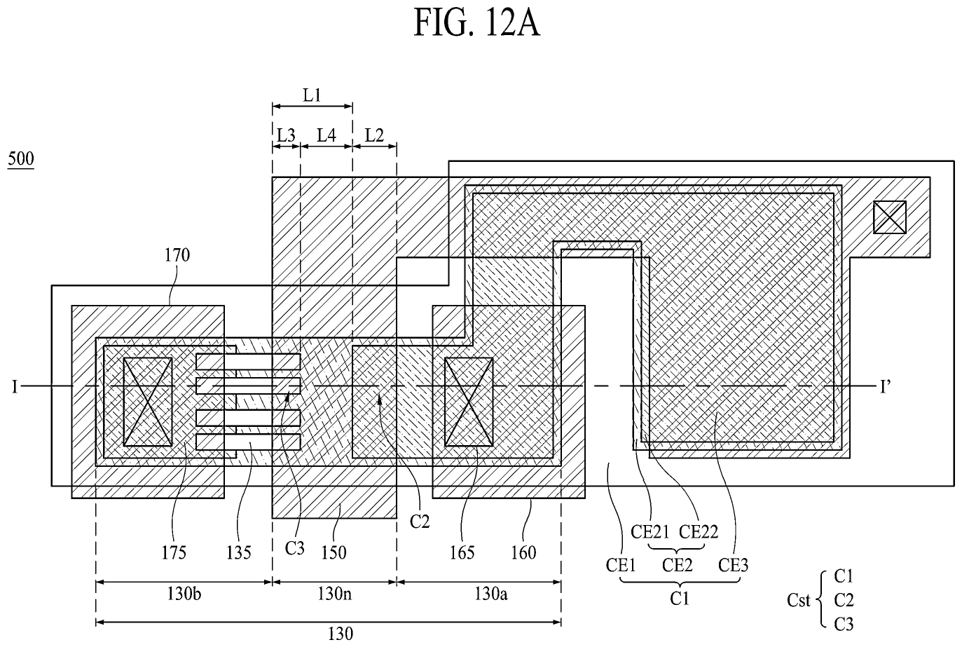

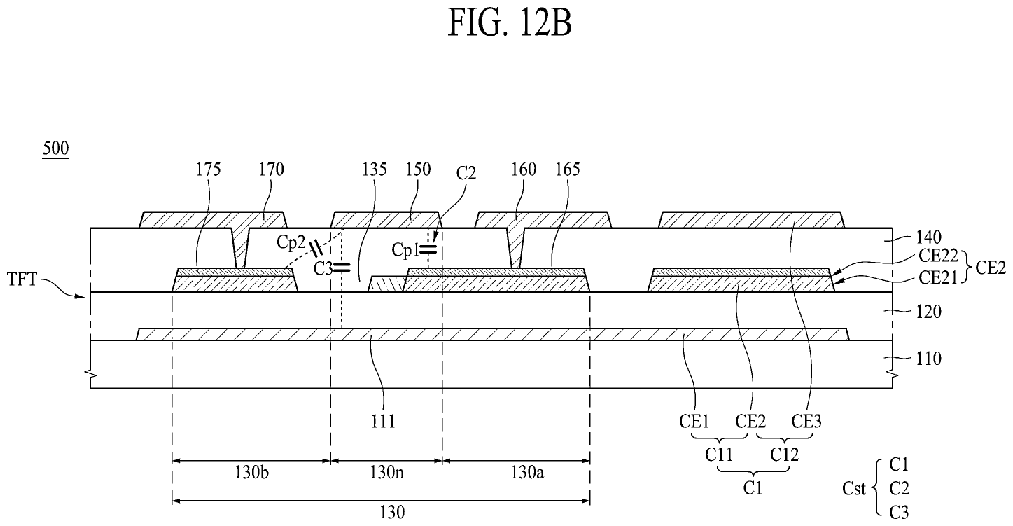

As a result, as shown in FIGS. 10, 12A, and 12B, when the second storage capacitor C2 is additionally formed on the thin film transistor substrate due to the first parasitic capacitor Cp1, the second storage capacitor C2 may be formed in parallel with the first storage capacitor C1, thereby easily securing a capacitor area and improving space efficiency.

On the other hand, as shown in FIG. 11, in the thin film transistor substrate according to the comparative example, because the first conductive material layer 165 does not overlap the gate electrode 150, the first parasitic capacitor Cp1 is not sufficiently secured, and thus the capacitor area may not be easily secured.

Also, because the thin film transistor substrate according to the comparative example does not include the active hole 135 in the drain area 130b, the second parasitic capacitor Cp2 is not minimized or reduced. Therefore, RC delay due to the second parasitic capacitor Cp2 may occur, and thus voltage charging becomes difficult. Also, the second parasitic capacitor Cp2 causes heat generation and an increase in current consumption of the transistor.

According to an embodiment of the present disclosure, the thin film transistor substrate may include a third storage capacitor. Compared with the thin film transistor substrate of FIG. 11, the thin film transistor substrate of FIG. 10 includes the active hole 135 protruding in the direction of the drain area 130b from the gate electrode 150 in a plan view and overlapping the gate electrode 150, and thus the gate electrode 150 and the light blocking layer 111 may include a third storage capacitor C3 formed to be spaced apart from each other and overlap each other.

According to an embodiment of the present disclosure, the third storage capacitor C3 is formed in a region where the gate electrode 150 and the light blocking layer 111 overlap the active hole 135.

As a result, as shown in FIGS. 10, 12A, and 12B, when the third storage capacitor C3 is additionally formed on the thin film transistor substrate according to an embodiment of the present disclosure, the third storage capacitor C3 may be formed in parallel with the first storage capacitor C1 and the second storage capacitor C2, thereby easily securing a capacitor area and improving space efficiency.

On the other hand, as shown in FIG. 11, because the thin film transistor substrate according to the comparative example does not include the active hole 135, the third storage capacitor C3 may not be secured, and thus the capacitor area may not be easily secured.

FIG. 12A is a plan view of a thin film transistor substrate according to another embodiment of the present disclosure. FIG. 12B is a cross-sectional view taken along line I-I′ of FIG. 12A.

According to an embodiment of the present disclosure, the thin film transistor substrate 500 includes a storage capacitor Cst. The storage capacitor Cst may be provided in an overlapping area between the light blocking layer 111 and the thin film transistor TFT.

According to an embodiment of the present disclosure, the storage capacitor Cst may include a first storage capacitor C1, and the first storage capacitor C1 may include a first capacitor electrode CE1 and a second capacitor electrode CE2. The first capacitor electrode CE1 and the second capacitor electrode CE2 may overlap each other to form a first capacitor C11.

According to an embodiment of the present disclosure, the first capacitor electrode CE1 may be connected to the light blocking layer 111. FIG. 12B illustrates a configuration in which the first capacitor electrode CE1 is connected to the light blocking layer 111.

According to an embodiment of the present disclosure, the second capacitor electrode CE2 may be connected to the active layer 130. The second capacitor electrode CE2 may be connected to one of the source area 130a and the drain area 130b. As illustrated in FIG. 12A, the second capacitor electrode CE2 may be connected to the source area 130a.

According to another embodiment of the present disclosure, the second capacitor electrode CE2 may include a first layer CE21 and a second layer CE22 on the first layer CE21. The second capacitor electrode CE2 may include a first layer CE21, which is formed integrally with any one of the source area 130a and the drain area 130b, and a second layer CE22 which is formed integrally with any one of the first conductive material layer 165 and the second conductive material layer 175.

In FIG. 12A, a configuration in which the second capacitor electrode CE2 includes a first layer CE21 integrally formed with the source area 130a and a second layer CE22 integrally formed with the first conductive material layer 165 is illustrated.

According to an embodiment of the present disclosure, because the second capacitor electrode CE2 may be formed by the active layer 130 and the conductive material layers 165 and 175, a separate process for forming the second capacitor electrode CE2 is not required, and as a result, space efficiency is improved, and the area of the second capacitor electrode CE2 may be increased.

With reference to FIGS. 12A and 12B, the thin film transistor substrate 500 according to an embodiment of the present disclosure may further include the third capacitor electrode CE3 connected to the gate electrode 150. The third capacitor electrode CE3 may be made of the same material as the gate electrode 150, the source electrode 160, and the drain electrode 170 by the same process.

According to an embodiment of the present disclosure, the second capacitor electrode CE2 and the third capacitor electrode CE3 may overlap each other to form a second capacitor C12. As the gate electrode 150 and the third capacitor electrode CE3 are connected to each other, the first capacitor electrode CE1 and the third capacitor electrode CE3 may be connected to each other, and the same voltage may be applied to the first capacitor electrode CE1 and the third capacitor electrode CE3.

With reference to FIGS. 12A and 12B, a second capacitor electrode CE2 is disposed between the first capacitor electrode CE1 and the third capacitor electrode CE3. As a result, it is possible to have the same effect as that two capacitors C11 and C12 are formed, with the second capacitor electrode CE2 interposed therebetween.

FIG. 13 is a schematic diagram illustrating a display apparatus 1000 according to further still another embodiment of the present disclosure.

As shown in FIG. 13, the display apparatus 1000 according to further still another embodiment of the present disclosure may include a display panel 310, a gate driver 320, a data driver 330 and a controller 340.

The display panel 310 includes gate lines GL and data lines DL, and pixels P are disposed in intersection areas of the gate lines GL and the data lines DL. An image is displayed by driving of the pixels P. The gate lines GL, the data lines DL and the pixels P may be disposed on the base substrate 110.

The controller 340 controls the gate driver 320 and the data driver 330. The controller 340 outputs a gate control signal GCS for controlling the gate driver 320 and a data control signal DCS for controlling the data driver 330 by using a signal supplied from an external system not shown. Also, the controller 340 samples input image data input from the external system, realigns the sampled data and supplies the realigned digital image data RGB to the data driver 330.

The gate control signal GCS includes a gate start pulse GSP, a gate shift clock GSC, a gate output enable signal GOE, a start signal Vst and a gate clock GCLK. Also, control signals for controlling a shift register may be included in the gate control signal GCS.

The data control signal DCS includes a source start pulse SSP, a source shift clock signal SSC, a source output enable signal SOE and a polarity control signal POL.

The data driver 330 supplies a data voltage to the data lines DL of the display panel 310. For example, the data driver 330 converts the image data RGB input from the controller 340 into an analog data voltage and supplies the data voltage to the data lines DL.

According to one embodiment of the present disclosure, the gate driver 320 may be packaged on the display panel 310. In this way, a structure in which the gate driver 320 is directly packaged on the display panel 310 will be referred to as a Gate In Panel (GIP) structure. In detail, in the Gate In Panel (GIP) structure, the gate driver 320 may be disposed on the base substrate 110.

The display apparatus 1500 according to one embodiment of the present disclosure may include the above-described thin film transistor substrates 100, 200, 300, 400, and 500. According to one embodiment of the present disclosure, the gate driver 320 may include the above-described thin film transistor substrates 100, 200, 300, 400, and 500.

The gate driver 320 may include a shift register 350. The shift register 350 sequentially supplies gate pulses to the gate lines GL for one frame by using the start signal and the gate clock, which are transmitted from the controller 340. In this case, one frame means a time period at which one image is output through the display panel 310. The gate pulse has a turn-on voltage capable of turning on a switching device (thin film transistor) disposed in the pixel P.

Also, the shift register 350 supplies a gate-off signal capable of turning off the switching device, to the gate line GL for the other period of one frame, at which the gate pulse is not supplied. Hereinafter, the gate pulse and the gate-off signal will be collectively referred to as a scan signal SS or Scan.

The shift register 350 may include the above-described thin film transistor substrates 100, 200, 300, 400, and 500.

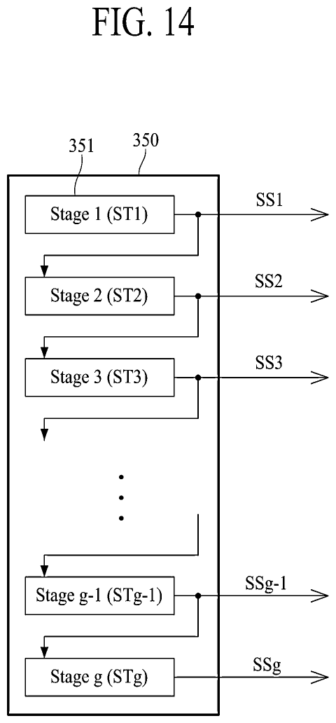

FIG. 14 is a schematic diagram illustrating a shift register 350.

As shown in FIG. 14, the shift register 350 may include g number of stages 351 (ST1 to STg). The shift register 350 transmits one scan signal SS to pixels P connected to one gate line GL through one gate line GL. Each of the stages 351 may be connected to one gate line GL. When g number of gate lines GL are formed in the display panel 310, the shift register 350 may include g number of stages 351 (ST1 to STg), and may generate g number of scan signals SS1 to SSg. In general, each stage 351 outputs the gate pulse GP once during one frame, and the gate pulses GP are sequentially output from each stage 351.

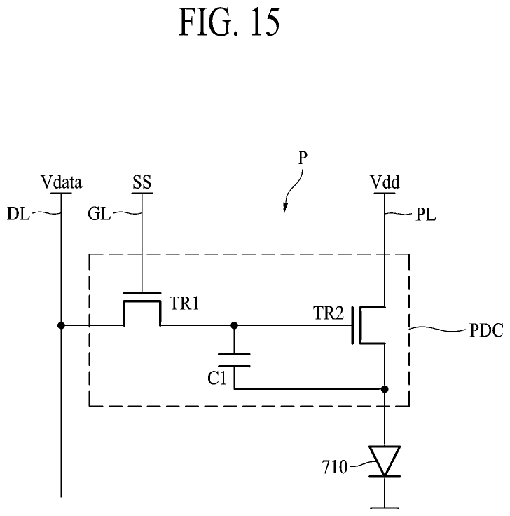

FIG. 15 is a circuit view illustrating any one pixel P of FIG. 13. The circuit view of FIG. 15 is an equivalent circuit view for the pixel P of the display apparatus 1000 that includes an organic light emitting diode (OLED) as a display element 710.

In FIG. 15, the pixel P includes a display element 710 and a pixel driving circuit PDC for driving the display element 710. For example, the display apparatus 1000 according to one embodiment of the present disclosure may include a pixel driving circuit PDC on the base substrate 110.

The pixel driving circuit PDC of FIG. 15 includes a first thin film transistor TR1 that is a switching transistor and a second thin film transistor TR2 that is a driving transistor. The display apparatus 1500 according to another embodiment of the present disclosure may include at least one of the above-described thin film transistor substrates 100, 200, 300, 400, and 500.

The first thin film transistor TR1 is connected to the gate line GL and the data line DL, and is turned on or off by the scan signal SS supplied through the gate line GL. The data line DL provides a data voltage Vdata to the pixel driving circuit PDC, and the first thin film transistor TR1 controls applying of the data voltage Vdata.

The driving power line PL provides a driving voltage Vdd to the display element 710, and the first thin film transistor TR1 controls the driving voltage Vdd. The driving voltage Vdd is a pixel driving voltage for driving the organic light emitting diode (OLED) that is the display element 710.

When the first thin film transistor TR1 is turned on by the scan signal SS applied from the gate driver 320 through the gate line GL, the data voltage Vdata supplied through the data line DL is supplied to a gate electrode of the second thin film transistor TR2 connected to the display element 710. The data voltage Vdata is charged in a storage capacitor C1 formed between the gate electrode and a source electrode of the second thin film transistor TR2.

The amount of a current supplied to the organic light emitting diode (OLED), which is the display element 710, through the second thin film transistor TR2 is controlled in accordance with the data voltage Vdata, whereby a gray scale of light output from the display element 710 may be controlled.

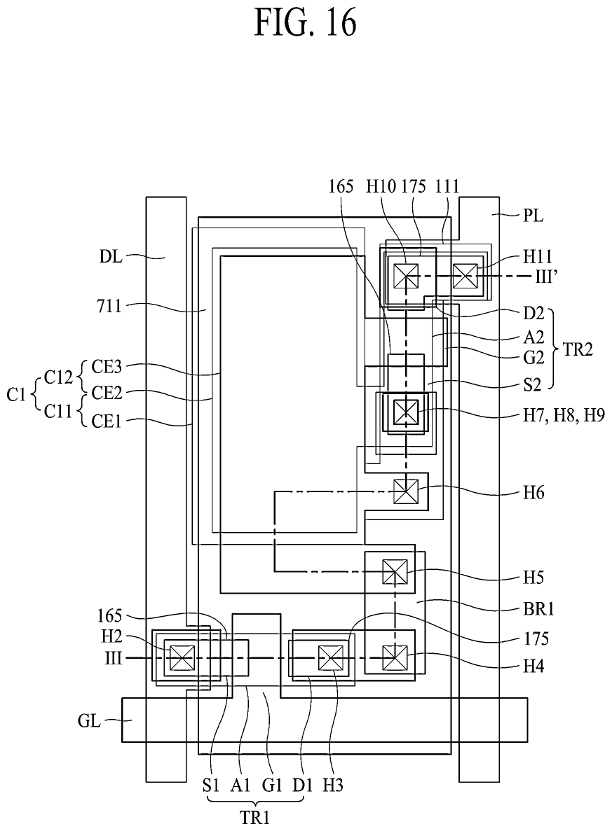

FIG. 16 is a plan view of the pixel of FIG. 15, and FIG. 17 is a cross-sectional view taken along line III-III′ of FIG. 16.

With reference to FIGS. 15 and 16, the first thin film transistor TR1 and the second thin film transistor TR2 are disposed on the base substrate 110. The first thin film transistor TR1 and the second thin film transistor TR2 include conductive material layers 165 and 175. The base substrate 110 may be made of glass or plastic. As the base substrate 110, plastic having flexible characteristics, for example, polyimide (PI), may be used.

The light blocking layer 111 is disposed on the base substrate 110. The light blocking layer 111 may have a light blocking characteristic. The light blocking layer 111 may block light incident from the outside to protect the active layers A1 and A2.

The buffer layer 120 is disposed on the light blocking layer 111. The buffer layer 120 is made of an insulating material and protects the active layers A1 and A2 from moisture or oxygen introduced from the outside. A first active layer A1 of the first thin film transistor TR1 and a second active layer A2 of the second thin film transistor TR2 are disposed on the buffer layer 120.

The first active layer A1 and the second active layer A2 may include, for example, an oxide semiconductor material. The first active layer A1 and the second active layer A2 may be formed of an oxide semiconductor layer made of an oxide semiconductor material.

In the first thin film transistor TR1, the first active layer A1 may include a channel area, a source area, and a drain area. A channel area of the first active layer A1 overlaps the gate electrode G1. According to another embodiment of the present disclosure, a source area may be referred to as a source electrode S1, and a drain area may be referred to as a drain electrode D1.

In the second thin film transistor TR2, the second active layer A2 may include a channel area, a source area, and a drain area. The channel area of the second active layer A2 overlaps the gate electrode G2. According to another embodiment of the present disclosure, a source area may be referred to as a source electrode S2, and a drain area may be referred to as a drain electrode D2.

In the first thin film transistor TR1, the first conductive material layer 165 is disposed on the source area of the first active layer A1 and overlaps the gate electrode G1. In the second thin film transistor TR2, the first conductive material layer 165 is disposed on the source area of the second active layer A2 and overlaps the gate electrode G2.

As shown in FIGS. 16 and 17, a part of the light blocking layer 111 may become the first capacitor electrode CE1 of the first capacitor C11. Also, a part of the second active layer A2 may be the second capacitor electrode CE2 of the first capacitor C11. Alternatively, it may be the second capacitor electrode CE2 of the second capacitor C12.

The gate insulating layer 140 is disposed on the first active layer A1 and the second active layer A2. The gate insulating layer 140 may cover the entire upper surfaces of the first active layer A1 and the second active layer A2, or may cover only a part of the first active layer A1 and the second active layer A2.

The gate electrode G1 of the first thin film transistor TR1 and the gate electrode G2 of the second thin film transistor TR2 are disposed on the gate insulating layer 140. A gate electrode G1 of the first thin film transistor TR1 overlaps at least a portion of the first active layer A1 of the first thin film transistor TR1. A gate electrode G2 of the second thin film transistor TR2 overlaps at least a portion of the second active layer A2 of the second thin film transistor TR2.

The source electrode S1 and the drain electrode D1 of the first thin film transistor TR1 are disposed on the gate insulation layer 140. Also, the source electrode S2 and the drain electrode D2 of the second thin film transistor TR2 are disposed on the gate insulation layer 140.

The source electrode S1 and the drain electrode D1 of the first thin film transistor TR1 are disposed on the same layer as the source electrode S2 and the drain electrode D2 of the second thin film transistor TR2. The gate electrode G1, the source electrode S1 and the drain electrode D1 of the first thin film transistor TR1, and the gate electrode G2, the source electrode S2, and the drain electrode D2 of the second thin film transistor TR2 are disposed on the same layer.

An interlayer insulating layer 180 is disposed on the gate electrodes G1 and G2, the source electrodes S1 and S2, and the drain electrodes D1 and D2. A data line DL and a driving power line PL are disposed on the interlayer insulating layer 180.

The data line DL contacts the first source electrode S1 formed in the first active layer A1 through the first contact hole H1. According to another embodiment of the present disclosure, a portion of the data line DL overlapping the first active layer A1 may be referred to as a first source electrode S1.

The driving power line PL is in contact with the second drain electrode D2 formed in the second active layer A2 through the eleventh contact hole H11. According to another embodiment of the present disclosure, a portion of the driving power line PL overlapping the second active layer A2 may be referred to as a second drain electrode D2.

With reference to FIGS. 16 and 17, a part of the gate electrode G2 of the second thin film transistor TR2 may be a third capacitor electrode CE3 of the second capacitor C12. The first capacitor electrode CE1 overlaps the second capacitor electrode CE2 to form a first capacitor C11. The second capacitor electrode CE2 overlaps the third capacitor electrode CE3 to form a second capacitor C12. A first bridge BR1 is disposed on the interlayer insulating layer 180. The first bridge BR1 is connected to the first drain electrode D1 through a fourth contact hole H4, and is connected to the third capacitor electrode CE3 of the second capacitor C12 through a fifth contact hole H5. The third capacitor electrode CE3 is connected to the light blocking layer 111 through the sixth contact hole H6.

The planarization layer 190 is disposed on the data line DL, the first bridge BR1, and the driving power line PL. The planarization layer 190 planarizes upper portions of the first thin film transistor TR1 and the second thin film transistor TR2 and protects the first thin film transistor TR1 and the second thin film transistor TR2.

The first electrode 711 of the display element 710 is disposed on the planarization layer 190. The first electrode 711 of the display element 710 is in contact with the second source electrode S2 of the second thin film transistor TR2 through the ninth contact hole H9 formed in the planarization layer 190 and the eighth contact hole H8 formed in the interlayer insulating layer 180. As a result, the first electrode 711 may be connected to the second source electrode S2 of the second thin film transistor TR2. Also, it is connected to the second active layer A2 through a seventh contact hole H7 formed in the gate insulating layer 140.

A bank layer 750 is disposed at an edge of the first electrode 711. The bank layer 750 defines a light emitting area of the display element 710. The organic light emitting layer 712 is disposed on the first electrode 711, and the second electrode 713 is disposed on the organic light emitting layer 712. Accordingly, the display element 710 is completed. The display element 710 shown in FIG. 17 is an organic light emitting diode (OLED). Therefore, the display apparatus 1000 according to an embodiment of the present disclosure is an organic light emitting display apparatus.

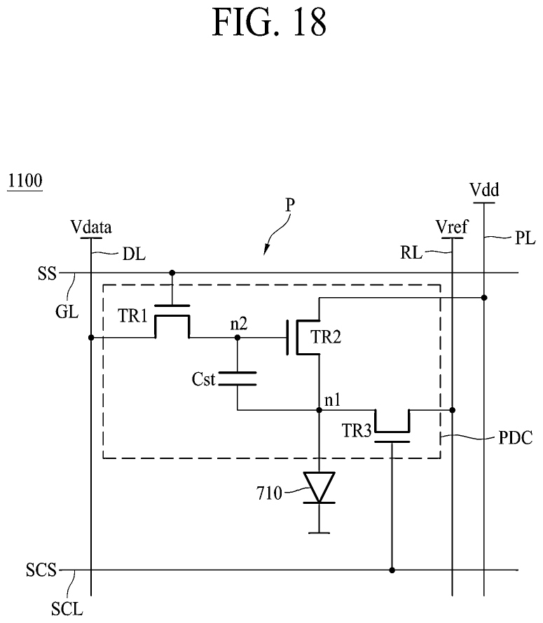

FIG. 18 is a circuit diagram of any one pixel of a display apparatus 1100 according to another embodiment of the present disclosure. FIG. 18 is an equivalent circuit diagram of a pixel P of an organic light emitting display apparatus.

The pixel P of the display apparatus 1100 shown in FIG. 18 includes an organic light emitting diode OLED, which is a display element 710, and a pixel driving circuit PDC for driving the display element 710. The display element 710 is connected to the pixel driving circuit PDC.

Signal lines DL, GL, PL, RL, and SCL for supplying signals to the pixel driving circuit PDC are arranged in the pixel P. The data voltage Vdata is supplied to the data line DL, the scan signal SS is supplied to the gate line GL, the driving voltage Vdd for driving the pixel is supplied to the driving power line PL, the reference voltage Vref is supplied to the reference line RL, and the sensing control signal SCS is supplied to the sensing control line SCL.

The pixel driving circuit PDC includes, for example, the first thin film transistor TR1 (switching transistor) connected to the gate line GL and the data line DL, the second thin film transistor TR2 (driving transistor) that controls the magnitude of the current output to the display element 710 according to the data voltage Vdata transmitted through the first thin film transistor TR1, and the third thin film transistor TR3 (sensing transistor) for sensing the characteristics of the second thin film transistor TR2.

The first thin film transistor TR1 is turned on by the scan signal SS supplied to the gate line GL, and transmits the data voltage Vdata supplied to the data line DL to the gate electrode of the second thin film transistor TR2. The third thin film transistor TR3 is connected to the first node n1 between the second thin film transistor TR2 and the display element 710 and the reference line RL, is turned on or off by the sensing control signal SCS, and detects characteristics of the second thin film transistor TR2, which is a driving transistor during the sensing period. A second node n2 connected to the gate electrode of the second thin film transistor TR2 is connected to the first thin film transistor TR1. A storage capacitor Cst is formed between the second node n2 and the first node n1.

When the first thin film transistor TR1 is turned on, the data voltage Vdata supplied through the data line DL is supplied to the gate electrode of the second thin film transistor TR2. The data voltage Vdata is charged in the storage capacitor Cst formed between the gate electrode and the source electrode of the second thin film transistor TR2. When the second thin film transistor TR2 is turned on, current is supplied to the display element 710 through the second thin film transistor TR2 by the driving voltage Vdd driving the pixel, and light is output from the display element 710.

The display apparatus 1100 according to another embodiment of the present disclosure may include at least one of the thin film transistor substrates 100, 200, 300, 400, and 500.

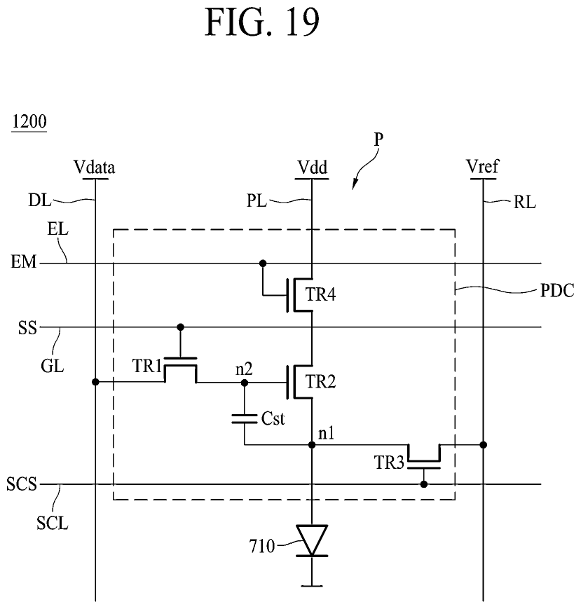

FIG. 19 is a circuit diagram of any one pixel P of a display apparatus 1200 according to another embodiment of the present disclosure.

The pixel P of the display apparatus 1200 shown in FIG. 19 includes an organic light emitting diode OLED, which is a display element 710, and a pixel driving circuit PDC for driving the display element 710. The display element 710 is connected to the pixel driving circuit PDC. The pixel driving circuit PDC includes thin film transistors TR1, TR2, TR3, and TR4. Signal lines DL, EL, GL, PL, SCL, and RL that supply driving signals to the pixel driving circuit PDC are arranged in the pixel P.

Compared with the pixel P of FIG. 18, the pixel P of FIG. 19 further includes an emission control line EL. The emission control signal EM is supplied to the emission control line EL. Also, compared with the pixel driving circuit PDC of FIG. 18, the pixel driving circuit PDC of FIG. 19 further includes a fourth thin film transistor TR4, which is an emission control transistor for controlling an emission time point of the second thin film transistor TR2.

The first thin film transistor TR1 is turned on by the scan signal SS supplied to the gate line GL, and transmits the data voltage Vdata supplied to the data line DL to the gate electrode of the second thin film transistor TR2. A storage capacitor Cst is positioned between the gate electrode of the second thin film transistor TR2 and the display element 710.

The third thin film transistor TR3 is connected to the reference line RL, is turned on or off by the sensing control signal SCS, and detects characteristics of the second thin film transistor TR2, which is a driving transistor, during the sensing period. The fourth thin film transistor TR4 transfers the driving voltage Vdd to the second thin film transistor TR2 or blocks the driving voltage Vdd according to the emission control signal EM. When the fourth thin film transistor TR4 is turned on, a current is supplied to the second thin film transistor TR2 to output light from the display element 710.

The pixel driving circuit PDC according to another exemplary configuration of the present disclosure may be formed in various structures other than the structure described above. The pixel driving circuit PDC may include, for example, five or more thin film transistors.

According to the present disclosure, the following advantageous effects may be obtained.

The thin film transistor substrate according to an embodiment of the present disclosure may include an active hole to prevent or suppress exposure of hydrogen and light to a channel.

The thin film transistor substrate according to an embodiment of the present disclosure may include an active hole to prevent or suppress the threshold voltage Vth from being shifted in a negative (−) direction.

The thin film transistor substrate according to an embodiment of the present disclosure may include a conductive material layer overlapping a channel area to prevent or suppress exposure of hydrogen and light to a channel.

The thin film transistor substrate according to an embodiment of the present disclosure comprises an active hole and includes a conductive material layer overlapping a channel area, thereby having stability and excellent reliability.

The thin film transistor substrate according to an embodiment of the present disclosure comprises an active hole and includes a conductive material layer overlapping a channel area, thereby ensuring capacitor area optimization.

It will be apparent to those skilled in the art that various modifications and variations can be made in the thin film transistor substrate and the display apparatus including the same of the present disclosure without departing from the technical idea or scope of the disclosure. Thus, it is intended that the present disclosure cover the modifications and variations of this disclosure provided they come within the scope of the appended claims and their equivalents.

What is claimed is:

1. A thin film transistor substrate, comprising:
a substrate;
a thin film transistor on the substrate,
wherein the thin film transistor includes:
an active layer;
a conductive material layer on the active layer; and
a gate electrode spaced apart from the active layer and partially overlapping the active layer,
wherein the active layer includes:
a channel area partially overlapping the gate electrode in a plan view;
a source area connected to one side of the channel area in the plan view; and
a drain area connected to the other side of the channel area in the plan view,
wherein the conductive material layer includes:
a first conductive material layer on the source area; and
a second conductive material layer on the drain area,
wherein the first conductive material layer overlaps at least a portion of the channel area,
wherein the active layer includes an active hole in which the active layer is absent within an area defined by the active layer, and
wherein, in the plan view, the active hole extends from the channel area to the drain area.

2. The thin film transistor substrate of claim 1, wherein a portion of the active hole overlaps the gate electrode in the plan view.

3. The thin film transistor substrate of claim 1, wherein the active hole is spaced apart from the first conductive material layer in the plan view.

4. The thin film transistor substrate of claim 1, wherein the second conductive material layer is spaced apart from the channel area in the plan view.

5. The thin film transistor substrate of claim 1, wherein the source area and the drain area are between the base substrate and the first conductive material layer and the second conductive material layer, respectively, and
wherein the first conductive material layer and the second conductive material layer respectively contact the active layer.

6. The thin film transistor substrate of claim 1, further comprising a source electrode and a drain electrode spaced apart from each other and respectively contacting the source area and the drain area, and
wherein the gate electrode, the source electrode, and the drain electrode are on the same layer.

7. The thin film transistor substrate of claim 1, wherein the active hole has a plurality of sub-active holes,
wherein the plurality of sub-active holes is spaced apart from each other, and
wherein each of the plurality of sub-active holes have an elongated shape extends from the channel area to the drain area.

8. The thin film transistor substrate of claim 1, wherein the conductive material layer includes at least one selected from titanium (Ti), molybdenum (Mo), aluminum (Al), silver (Ag), copper (Cu), chromium (Cr), tantalum (Ta), neodium (Nd), calcium (Ca), barium (Ba), and transparent conductive oxide (TCO).

9. The thin film transistor substrate of claim 1, wherein a shortest distance from the drain area to the first conductive material layer is a first length,
wherein a shortest length in a channel length direction of the active layer that the first conductive material layer overlaps the gate electrode in the plan view is a second length, and
wherein the first length is longer than the second length.

10. The thin film transistor substrate of claim 1, wherein a portion of the active hole overlaps the gate electrode,
wherein a shortest length in a channel length direction of the active layer that the active hole overlaps the gate electrode is a third length,
wherein a shortest distance from the active hole to the first conductive material layer in the channel length direction of the active layer is a fourth length, and
wherein the fourth length is longer than the third length.

11. The thin film transistor substrate of claim 1, further comprising:
a light blocking layer on the substrate; and
a storage capacitor in an overlapping area between the light blocking layer and the thin film transistor.

12. The thin film transistor substrate of claim 11, wherein the storage capacitor includes a first storage capacitor, the first storage capacitor including:
a first capacitor electrode connected to the light blocking layer; and
a second capacitor electrode connected to the active layer, and
wherein the first capacitor electrode and the second capacitor electrode are spaced apart from each other and overlap each other to form a first capacitor.

13. The thin film transistor substrate of claim 12, wherein the first storage capacitor includes a third capacitor electrode connected to the gate electrode, and
wherein the second capacitor electrode and the third capacitor electrode are spaced apart from each other and overlap each other to form a second capacitor.

14. The thin film transistor substrate of claim 12, wherein the second capacitor electrode includes:
a first layer integrated with any one of the source area and the drain area; and
a second layer integrated with any one of the first conductive material layer and the second conductive material layer.

15. The thin film transistor substrate of claim 13, wherein the second capacitor electrode is between the first capacitor electrode and the third capacitor electrode, and
wherein the third capacitor electrode is connected to the first capacitor electrode.

16. The thin film transistor substrate of claim 11, wherein the storage capacitor includes a second storage capacitor formed by separating and overlapping the gate electrode and the first conductive material layer.

17. The thin film transistor substrate of claim 11, wherein the storage capacitor includes a third storage capacitor formed by separating and overlapping the gate electrode and the light blocking layer from each other.

18. The thin film transistor substrate of claim 17, wherein the third storage capacitor is in an area overlapping the active hole.

19. The thin film transistor substrate of claim 1, wherein the active layer includes an oxide semiconductor material, and
wherein the oxide semiconductor material includes at least one of IZO (InZnO)-based, IGO (InGaO)-based, ITO (InSnO)-based, IGZO (InGaZnO)-based, IGZTO (InGaZnSnO)-based, GZTO (GaZnSnO)-based, GZO (GaZnO)-based, ITZO (InSnZnO)-based, and FIZO (FelnZnO)-based oxide semiconductor materials.

20. A display apparatus comprising the thin film transistor substrate of claim 1.
